(19) United States
(12) Patent Application Publication
(10) Pub. No.: US 2011/0005590 A1
(43) Pub. Date: Jan. 13, 2011

(54) Tandem Photoelectrochemical Cell for Water Dissociation

(75) Inventors: Wladyslaw Walukiewicz, Kensington, CA (US); Iulian Gherasoiu, Gilbert, AZ (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(73) Assignee: RoseStreet Labs Energy, Inc., Phoenix, AZ (US)

(21) Appl. No.: 12/833,790

(22) Filed: Jul. 9, 2010

Related U.S. Application Data
(60) Provisional application No. 61/224,212, filed on Jul. 9, 2009.
(60) Provisional application No. 61/291,327, filed on Dec. 30, 2009.

(51) Int. Cl. H01L 31/02

(52) U.S. Cl. 136/256

(57) ABSTRACT

A tandem photoelectrochemical (PEC) cell including a nitride PEC semiconductor connected in series with a current matched photovoltaic (PV) Si solar cell that provides an internal biasing voltage. A low resistance tunnel junction is formed between the PEC semiconductor and PV cell. The tandem PEC cell is placed together with a counter electrode in contact with an aqueous solution, such that, when exposed to solar radiation, the PEC semiconductor utilizes high energy photons to split water while the PV cell utilizes low energy photons to bias the tandem PEC cell to eliminate the barrier between Fermi energy and redox potentials, thereby initiating the spontaneous dissociation of water in the aqueous solution into hydrogen and oxygen. The conduction band edge (CBE) for n-type PEC semiconductor is located in the vicinity of the Fermi stabilization energy to reduce the barriers for the charge transfer between the PEC semiconductor and the aqueous solution.

### CROSS REFERENCE To RELATED APPLICATION(S)

This application claims priority to U.S. Provisional Patent Application Ser. No. 61/224,212, entitled “Tandem Nitride Photoelectrochemical Cell for Water Dissociation,” filed on Jul. 9, 2009, and to U.S. Provisional Patent Application Serial No. 61/291,327, entitled “Tandem Photoelectrochemical Cell for Water Dissociation,” filed on Dec. 30, 2009, the contents of each of which are incorporated herein by reference in their entireties.

### BACKGROUND OF THE INVENTION

1. Field of the Invention

The invention relates generally to the generation of hydrogen and oxygen from water using solar radiation to enable photo-electrolysis processes and, more particularly, to a tandem photoelectrochemical cell for the dissociation of water to generate hydrogen and oxygen.

2. Background Discussion

Photoelectrochemical (PEC) cells are devices that use energy of photons to initiate chemical reactions in electrolyte. Specifically, PECs referred to in this application utilize solar photons to dissociate water into oxygen and hydrogen. A solar PEC consists of semiconductor film with one surface in contact with electrolyte. The other surface is connected to a metallic counterelectrode immersed in the same electrolyte. The water dissociation process occurs when the polar covalent bond of the water molecule is broken. In the case of PEC cells, solar radiation photons produce electrons in the conduction band and holes in the valence band of the semiconductor material. In order to achieve water splitting (or dissociation), it is necessary for the conduction and valence band edges of the semiconductor straddle the H⁺/H₂O and O₂/H₂O redox potentials. When this condition is satisfied, two photo-excited holes in the valence band of the semiconductor could migrate to the semiconductor-electrolyte interface where they react with water breaking-up a H₂O molecule into an O atom and two positively charged H⁺ions. The electrons in the conduction band of the semiconductor move to the counter electrode, where passing into the electrolyte volume they could neutralize the H⁺ions. As the result of the reaction the O₂ is formed on the semiconductor-electrolyte interface and H₂ on the counterelectrode. The hydrogen redox (H⁺/H₂O), located at about 4.5 eV below the vacuum level, lies 1.23 eV apart from the oxygen redox (H₂O/O₂) potential.

Some conventional attempts of utilizing photoelectrochemical processes at a semiconductor-liquid interface to induce water splitting have required the use of external biasing of the two electrodes in addition to the photo-carriers generated through illumination, where the external bias was used to provide a proper alignment of the band edges. These prior attempts suffered the inconvenience of having to supply an external bias to induce water splitting. Other conventional attempts of utilizing PEC to induce water splitting altered the band alignment at the semiconductor-liquid interfaces through modification of chemical potentials.

There have been some proposed solutions for achieving unassisted or spontaneous water splitting using an internal bias based on a series of separate PEC elements and photovoltaic (PV) cells that have been largely ineffective and/or inefficient based the failure to achieve or recognize numerous important principles of operation for inducing unassisted or spontaneous water splitting set forth by the present invention.

### SUMMARY

A tandem photoelectrochemical (PEC) cell is provided for the spontaneous dissociation of water into hydrogen and oxygen upon exposure to solar radiation. The PEC cell includes a PEC semiconductor connected in series with a current matched PV solar cell, where the PV cell provides an internal voltage bias for the PEC semiconductor.

In accordance with one or more embodiments, the PEC semiconductor of the PEC cell includes a photoactive material for absorbing a portion of the solar spectrum upon exposure to the solar radiation to generate electron-hole pairs in the PEC semiconductor, while the PV cell also includes a photoactive material that is configured to absorb a portion of the solar spectrum upon exposure to the solar radiation so as to generate a biasing voltage for the PEC semiconductor. The PEC semiconductor and the PV cell are configured such that one of the conduction band (valence band) of the PEC semiconductor is aligned with a corresponding other of the valence band (conduction band) of the biasing PV cell, depending upon whether the PEC semiconductor is n-type (p-type), so as to form a low resistance tunnel junction between the PEC semiconductor and the PV cell. This low resistance tunnel junction provides a perfect ohmic (no barrier) contact that facilitates the recombination of electrons and holes at the interface between the PEC semiconductor and the PV cell. For example, the conduction band edge (CBE) of the PEC semiconductor is aligned (e.g., within +/−0.3 eV) with the valence band edge (VBE) of the PV cell in n-type PEC semiconductor and the VBE of PEC semiconductor is aligned (within +/−0.3 eV) with the CBE of the PV cell in p-type PEC semiconductor. By providing an alignment of 0.3 eV or less, the barrier between the PEC semiconductor and the PV cell would not constitute any significant impediment for electron/hole recombination at room temperature.

In accordance with one or more embodiments, the tandem PEC cell is formed as a multi-layer, solid-state semiconductor in which certain layers comprise the PEC semiconductor and certain layers comprise the PV cell. An additional layer of the multi-layer structure includes an ohmic contact of a conductive material deposited on a surface of the PV cell. The multi-layer tandem PEC cell then functions as a work electrode when immersed in water or an aqueous solution with a counter electrode such that solar radiation imparted on the tandem PEC cell enables photo-electrolysis processes in the aqueous solution Upon exposure to solar radiation, the PV cell generates an internal biasing voltage for the PEC semiconductor while the PEC semiconductor generates electron-hole pairs that interact with water present in the aqueous solution for causing dissociation of the water involving a reduction process to generate hydrogen and an oxidation process to generate oxygen.

In accordance with one or more embodiments, the CBE and VBE of the PEC semiconductor are formed to straddle the hydrogen (H⁺) and oxygen (O₂) redox potentials (i.e., the reduction and oxidation potentials) so that the redox potentials are included within the energy span between the CBE and VBE of the PEC semiconductor. In one or more embodiments, the PV cell is configured to generate a bias voltage that causes the CBE and VBE of the PEC semiconductor to straddle the hydrogen (H⁺) and oxygen (O₂) redox potentials. The bias voltage generated by the PV cell further raises the Fermi energy level at the counter electrode to align the CBE or VBE of the PEC semiconductor with the Fermi energy level of the aqueous solution to reduce the barriers for charge transfer between the PEC semiconductor and the aqueous solution. For example, the CBE for n-type PEC semiconductor and the VBE for p-type PEC semiconductor must be substantially aligned (E_{FS} +/−0.3 eV) to remove the energy discontinuity at the interface between the PEC semiconductor and the aqueous solution. In one or more embodiments, the PV cell is configured to generate a biasing voltage of at least 0.4 V when the PEC semiconductor comprises an n-type semiconductor and a biasing voltage of at least 0.83 V when the PEC semiconductor comprises an p-type semiconductor.

In one or more embodiments, the tandem PEC cell is formed such that the PEC semiconductor possesses a band gap between 1.7 eV to 1.9 eV, preferably as close to 1.7 eV as possible, while the PV cell possesses a band gap of approximately 1.1 eV. In one or more embodiments, the PEC semiconductor comprises a nitride semiconductor layer and the PV cell comprises a silicon substrate. In one or more embodiments, the nitride semiconductor layer forming the PEC semiconductor may specifically comprise an alloy of Inₓ Al_{y} Ga_{1-x-y}N, where 0≦x, y≦1.

In accordance with one or more embodiments, tandem PEC cell is formed to possess two p-n junctions, with the PEC semiconductor formed to include a first p-n semiconductor junction and the PV cell configured to include a second p-n semiconductor junction. In some embodiments, the first p-n semiconductor junction formed in the PEC semiconductor is formed between a p-type layer of Inₓ Al_{y} Ga_{1-x-y}N and an n-type layer of Inₓ Al_{y} Ga_{1-x-y}N, where 0≦x, y≦1, and the second p-n semiconductor junction formed in the PV cell is formed between a p-type layer of Si and an n-type layer of Si.

In accordance with one or more embodiments, a tandem PEC cell is provided that allows efficient, spontaneous dissociation of water into hydrogen and oxygen by satisfying some or all of the following conditions:
1.The PEC semiconductor band gap is selected to be as small as possible (i.e., between 1.7 to 1.9 eV, preferably as close to 1.7 eV as possible) to maximize the absorbed solar energy.
2. In n-type PEC semiconductor, the valence band edge (VBE) has to be located below the oxygen redox potential whereas in the p-type PEC semiconductor, the conduction band edge (CBE) has to be above the hydrogen redox potential.
3. The biasing PV cell has to provide at least 0.4 V for n-type PEC semiconductor and at least 0.83 V for p-type PEC semiconductor.
4.The conduction band edge (CBE) for n-type PEC semiconductor and the valence band edge (VBE) for p-type PEC semiconductor has to be located in the vicinity of the Fermi stabilization energy (E_{FS}) (within an approximate range E_{FS} +/−0.3 eV) to reduce the barriers for the charge transfer between the PEC semiconductor and the aqueous solution.
5. To facilitate recombination of electrons and holes at the interface between the PEC semiconductor and PV cell, the CBE of the PEC semiconductor has to be substantially aligned (within +/−0.3 eV) with the VBE of the PV cell, assuming that the PEC semiconductor is n-type.
6. The materials in the tandem PEC cell are preferably, although not required to be, resistant to corrosion from the aqueous solution.

In accordance with one or more embodiments, the material systems constituting the tandem PEC cell that are the subject of one or more embodiments described herein provide a simple and efficient solution for the device that may satisfy all of the above-listed conditions for efficient solar water dissociation.

### DRAWINGS

The features and objects of the present disclosure will become more apparent with reference to the following description taken in conjunction with the accompanying drawings and in which:

FIG. 1 is a block schematic illustration of the layers of a tandem photoelectrochemical (PEC) cell in accordance with one or more embodiments of the present disclosure.

FIG. 2 is a block schematic illustration of the layers of a tandem photoelectrochemical (PEC) cell in accordance with one or more embodiments of the present disclosure.

FIG. 3a is a graphical illustration of the energy barriers that develop at the interface between n-type or p-type semiconductors and electrolyte.

FIG. 3b illustrates the “flattening” of the energy barriers with the application of a voltage bias across n-type or p-type semiconductors and electrolyte circuit.

FIG. 4 is a depiction of the conduction and valence band edges for the InₓAl_{y}Ga_{1-x-y}N alloys in relation to the lowest position that can be occupied by the conduction band edge E_{g}(min) of any such alloy for the nitride-silicon tandem PEC cell to operate spontaneously.

FIG. 5 is a representation of a tandem PEC device that exhibits proper band alignment using the internal bias from a silicon PV cell for a nitride PEC semiconductor in accordance with one or more embodiments of the present disclosure, with indications of the tolerance of various band alignments within which the spontaneous water splitting occur.

FIG. 6 is a representation of the band alignment and operation mechanism of the single-junction tandem PEC device in accordance with one or more embodiments of the present disclosure.

FIG. 7 is a block diagram representation of the layers of a tandem nitride photoelectrochemical (PEC) cell in accordance with one or more embodiments of the present disclosure.

FIG. 8 is a representation of the band alignment and operation mechanism of the dual-junction tandem PEC device in accordance with one or more embodiments of the present disclosure.

### DETAILED DESCRIPTION

The following description and drawings are illustrative and are not to be construed as limiting. Numerous specific details are described to provide a thorough understanding. However, in certain instances, well known or conventional details are not described to avoid obscuring the description. References to one or an embodiment in the present disclosure are not necessarily references to the same embodiment; and, such references mean at least one. The use of headings herein are merely provided for ease of reference, and shall not be interpreted in any way to limit this disclosure or the claims.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

According to one or more embodiments described herein, a tandem photoelectrochemical (PEC) cell is provided comprising a multi-layer, solid-state semiconductor that constitutes a work electrode that is immersed in water or an aqueous solution together with a counter electrode such that solar radiation imparted on the tandem PEC cell enables photo-electrolysis processes in the aqueous solution (e.g., water) for the spontaneous generation of hydrogen and oxygen. In one or more embodiments described herein, the tandem PEC cell may be described or exemplified as a semiconductor (SC)-silicon tandem PEC cell or a tandem nitride-silicon PEC cell, but it should be understood to those skilled in the art, that such operation and properties of the tandem PEC cell are not limited to the nitride-silicon tandem PEC cell examples set forth herein and the principles of these embodiments may be applied to any SC-silicon tandem PEC cell that complies with the band gap properties described herein.

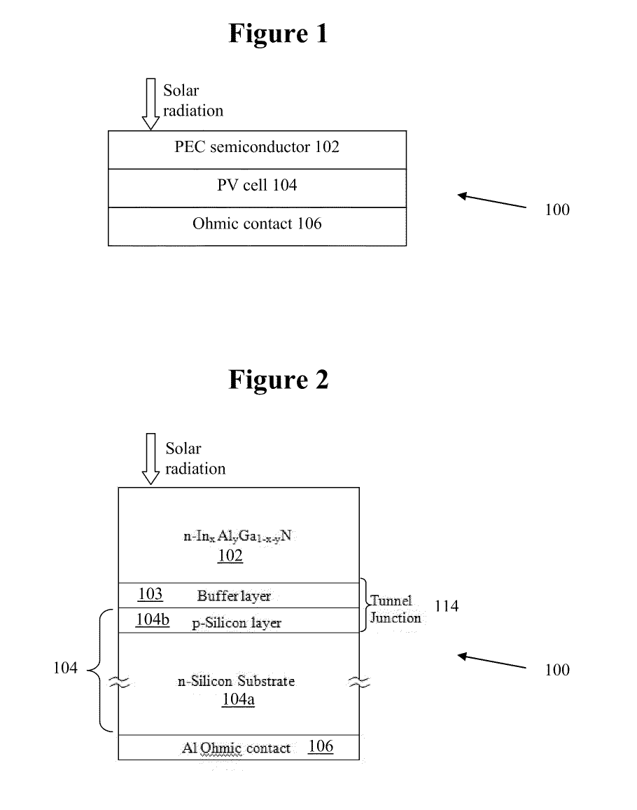

Referring now to FIG. 1, in one or more embodiments, a tandem photoelectrochemical (PEC) cell 100 is provided that includes a PEC semiconductor 102 connected in series with a current matched PV solar cell 104. An ohmic electrical contact 106 is connected to an opposite surface of the PV solar cell 104 from the PEC semiconductor 102. The ohmic contact 106 may comprise any electrically conductive material that may be formed together with the multi-layer, tandem PEC cell 100 in accordance with the principles of operation of the various embodiments described herein.

In one or more embodiments, the tandem PEC cell 100, which functions as a work electrode, comprises a multi-layer semiconductor structure where each semiconductor layer is a photoactive material absorbing part of the incident solar radiation in a process that generates electron-hole pairs. Referring now to FIG. 2, in one or more embodiments, a first layer of the multi-layer structure for the tandem PEC cell 100 is formed from mono-crystalline silicon, which functions as PV cell 104. The silicon layer or substrate comprises n-type silicon, where the upper surface of the n-type silicon layer is doped with a p-type dopant so as to form a p-n junction in the silicon layer so that it functions as a PV cell 104. For example, in one embodiment as illustrated in FIG. 2, the silicon substrate 104 is an n-type silicon wafer 104a that undergoes a brief doping process so that the top surface of the silicon substrate is diffused with the appropriate dopant to form a p-doped silicon layer 104b over an n-type silicon layer 104a. Such a dopant could be for example aluminum (Al) or any other commonly known p-dopant, including but not limited to such as boron (B), gallium (Ga) or indium (In). It is understood that the doping procedures could be performed either before other layers of the multi-layer structure are deposited or during the deposition process of other layers. The silicon substrate 104 could also comprise polycrystalline, micro-crystalline or even amorphous silicon. In one or more embodiments, a buffer layer 103 may be deposited on the PV cell 104 (e.g., on p-doped silicon layer 104b) prior to the PEC semiconductor 102 to facilitate the growth of the PEC semiconductor 102. In one or more embodiments, the buffer layer 103 may comprise a thin nitride film, such as SiNX, AlN, GaN, or any other thin film combination that accommodates the lattice mismatch with the silicon substrate of PV cell 104 and facilitates the growth of the nitride PEC semiconductor 102.

A layer of PEC semiconductor material 102 is then deposited on the silicon substrate 104 by any appropriate epitaxial method (e.g., molecular beam epitaxy, MBE, MOCVD, HVPE, or other suitable deposition technique). In one or more embodiments, the PEC semiconductor 102 comprises a nitride semiconductor layer having a band gap between approximately 1.7 eV to 1.9 eV. In one or more embodiments, the PEC semiconductor 102 possesses a band gap as close to 1.7 eV as possible to achieve the beneficial conditions for the spontaneous dissociation of water described herein. The nitride semiconductor layer 102 may comprise InₓGa₁₋ₓN, InₓAl₁₋ₓN, InₓAl_{y}Ga_{1-x-y}N or any other nitride semiconductor that satisfies the above band gap requirement, where 0≦x, y≦1. While certain embodiments described herein may describe InₓGa₁₋ₓN or InₓAl_{y}Ga_{1-x-y}N as exemplary materials, it is understood that other nitride semiconductor materials having similar attributes to achieve the beneficial conditions for the spontaneous dissociation of water described herein may be interchangeably used in place of these materials. In other embodiments, the PEC semiconductor material 102 may further comprise other materials that may be shown to satisfy the band gap requirements and other required conditions for the tandem PEC cell described herein, such as gallium nitride arsenide, zinc oxide selenide, etc.

In general, for the tandem nitride PEC cell 100 to spontaneously achieve water dissociation, the PEC semiconductor 102 has to posses a band gap that is larger than the H₂O redox energy of 1.23 eV. Thus, for water electrolysis, a minimum electric potential of 1.23 V is required, where it has been found that typically a cathodic over-potential of at least 0.1 V and anodic over-potential of at least 0.2 V are also necessary for water electrolysis. It has been experimentally determined that the photon energy has to be at least 0.4 to 0.5 eV higher than the 1.23 eV H₂O redox energy for water electrolysis to occur, where this over-potential compensates for energy losses in the dissociation reaction. Thus, in one or more embodiments, the materials selected for PEC semiconductor 102 preferably has a band gap as close to 1.7 eV as possible for the water splitting electronic processes to work to allow for the generation of hydrogen and oxygen, while such a bad gap also maximizes the photon absorption (by having as small band gap as possible) and also satisfies the condition for a perfect tunnel junction between the PEC semiconductor 102 and PV cell 104.

When doped, the particular PEC semiconductor 102 layer, besides having the appropriate band gap value, further has to exhibit a band edge alignment allowing the flat band potential and the band edge of the minority carriers to straddle the H⁺/H₂ and O₂/H₂O redox potentials. Moreover, the same PEC semiconductor 102 layer has to be capable of absorbing light in the visible part of the solar spectrum where the photon density is the largest.

When the PEC semiconductor 102 is contact with the aqueous solution, the conduction and valence band edges of the PEC semiconductor 102 straddle the H⁺/H₂O and O₂/H₂O redox potentials when the conduction band edge (CBE) of the PEC semiconductor 102 is positioned above, or closer to the vacuum level with respect to the H⁺/H₂O redox potential, and when the valence band edge of the PEC semiconductor 102 is positioned below, or farther from the vacuum level, with respect to the O₂/H₂O redox potential. In this configuration, the H⁺/H₂O and O₂/H₂O redox potentials are included within the energy span from valence to the conduction band edges of the PEC semiconductor 102. The effect of this energetic arrangement is that electrons from the conduction band of the PEC semiconductor 102 are energetically favored toward crossing into the aqueous solution, by losing energy, and neutralize a H⁺ ion, while the electrons in the H₂O bond would be attracted into a lower energy state, the valence band of the PEC semiconductor 102, therefore releasing oxygen from its hydrogen pair.

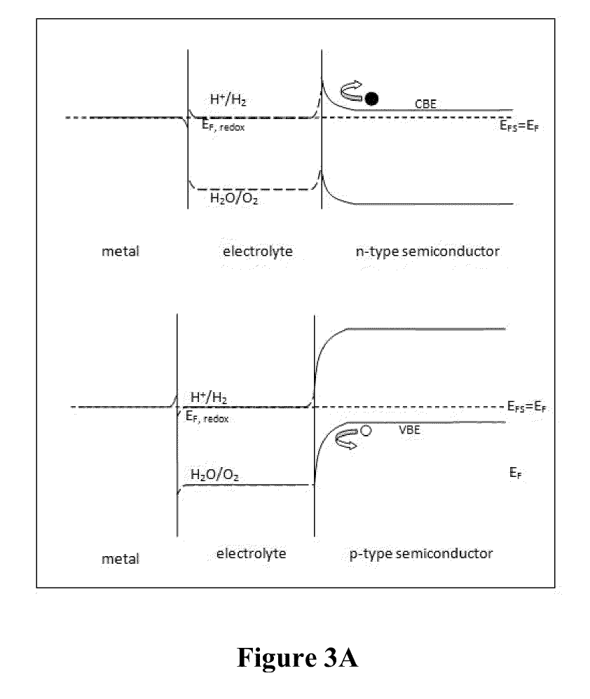

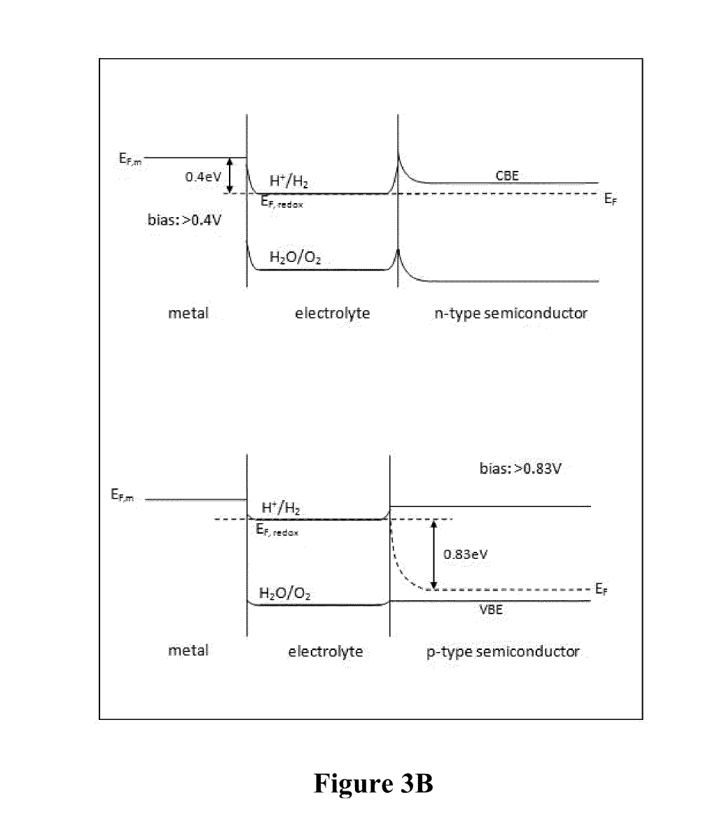

It should be noted that proper band alignment of the conduction and the valence band edges of the PEC semiconductor 102 with respect to the hydrogen and oxygen redox potentials is a necessary condition but not the only condition for the spontaneous light induced dissociation of water. The reason for this is that the Fermi energy on free semiconductor surfaces as well as on surfaces in contact with aqueous solution are strongly pinned at specific energy level called Fermi level stabilization energy E_{FS}. In all semiconductor materials, E_{FS} is a universal energy level located 4.9 eV below the vacuum level. In most semiconductors, E_{FS} lies in the band gap producing surface depletion layers in p- or n-type material. This, as is shown in FIG. 3A, places the bulk conduction band (in n-type) and the valence band (in p-type) at 4.9 eV below the vacuum level which prevents either the conduction band electrons to transfer to hydrogen redox or the valence band holes to transfer to the oxygen redox potential.

The H⁺ redox potential is situated at 4.5 eV below the vacuum energy for pH-neutral aqueous solutions. For n-type and p-type semiconductors, the Fermi energy level (E_{F}) at the PEC semiconductor 102/aqueous solution interface will be pinned at the E_{FS}, 4.9 eV, which is 0.4 eV below the hydrogen redox level. Since the E_{F} for n-type semiconductors is close to the conduction band edge, a bias of a minimum 0.4 V is necessary to lift the Fermi energy and remove the energy discontinuity present in the conduction band edge at the interface of an n-type PEC semiconductor 102 and the aqueous solution. For p-type semiconductors, the bias has to overcome the energy difference between the Fermi stabilization energy level, where the Fermi level is pinned at the PEC semiconductor 102/aqueous solution interface and the oxygen redox energy level (5.73 eV). Therefore, a bias of a minimum 0.83 V (5.73 eV−4.9 eV=0.83 V) is necessary to remove the energy discontinuity at the interface of a p-type PEC semiconductor 102 and an aqueous solution. Note that the bias has opposite direction for the n- and p-type semiconductors. As such, application of an additional voltage is required to induce the photo-dissociation of water. As illustrated in FIG. 3B, to initiate the water splitting reaction in the aqueous solution, a bias voltage higher than 0.4 V is needed for the n-type semiconductor and higher than 0.83 V for p-type semiconductor. In one or more embodiments, this bias voltage is provided by a smaller gap solar cell (PV cell 104) connected in series with the PEC semiconductor 102.

Based on the band gap size and band alignment requirements for the development of photoelectrochemical processes, an InₓGa₁₋ₓN semiconductor, for example, with a band gap narrower than 2.8 eV would typically possess a conduction band edge that is too positive, referenced to normal hydrogen electrode (NHE), to drive the water hydrogen reduction reaction and therefore it would require an additional external potential for water dissociation to occur. However, nitride alloys such as InₓGa₁₋ₓN, are almost ideal semiconductors with respect to the potential for band gap engineering, absorption coefficient and chemical stability.

The range of semiconductor materials suitable to spontaneously drive the water splitting reaction when operating in tandem with a silicon p/n junction could be extended to include any material that satisfies the band alignment conditions described above. Specifically, for a n-type PEC semiconductor 102 to satisfy these band alignment conditions, the conduction band edge (CBE) of such a material has to be positioned between +0.8 eV to −0.3 eV from the Fermi stabilization energy, E_{FS}, which is situated at 4.9 eV bellow the vacuum level. However, in order to further ensure that the CBE of the n-type PEC semiconductor 102 is substantially aligned with the VBE of the PV cell 104 as described herein as a necessary condition for operation of various embodiments, the CBE of the n-type PEC semiconductor 102 is preferably with +/−0.3 eV from the Fermi stabilization energy, E_{FS}. At the same time, the valence band edge (VBE) of the PEC semiconductor 102 must be positioned bellow the redox potential necessary for oxygen reduction, thus allowing holes current to pass from the semiconductor volume into the aqueous solution.

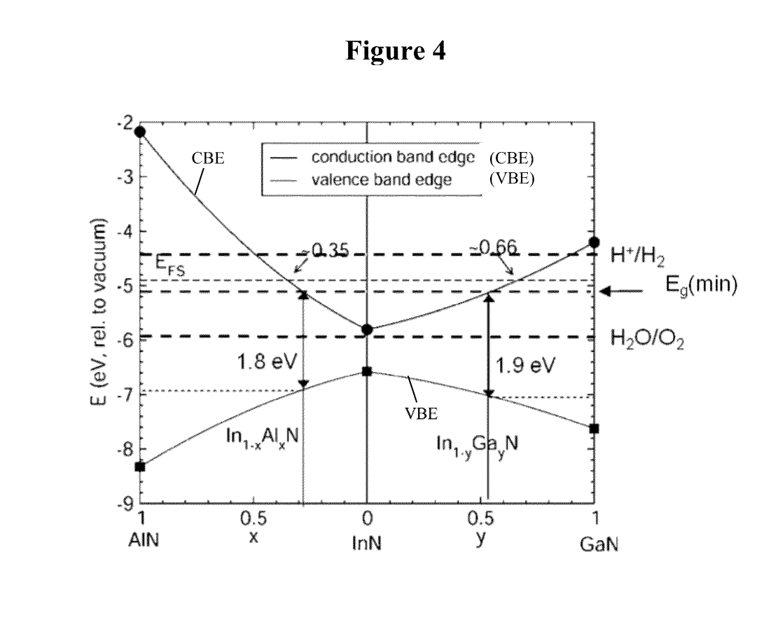

For conventional PEC cells described in previous solutions, InₓGa₁₋ₓN alloys with band gaps of 2.1 eV and 2.64 eV have been selected for the purpose of obtaining a greater overlap with the white light spectra used and subsequently better light absorption. However, none of these alloys could be used as working electrodes to generate hydrogen in water dissociation processes without external biasing. The explanation for this behavior can be found by analyzing the alignment of the InₓGa₁₋ₓN semiconductor conduction and valence bands with respect to the water redox levels, depicted by the band arrangement at the left-side in FIG. 4. As can be seen, for both InₓGa₁₋ₓN compositions, one with indium fraction of ˜36% (E_{g}=2.1 eV) and the other one with indium fraction of ˜20% (E_{g}=2.64 eV), the conduction band edge was situated below the reduction potential of hydrogen. This alignment provides a potential barrier for the transport of electrons from the nitride semiconductor layer to the water in which it is situated. In order to overcome this barrier, one would have to apply an external voltage and alter the band alignment to the appropriate manner. Although this can be done, it represents an undesired energy expense and a supplementary technical complication.

The unimpeded carrier flow over the semiconductor-liquid junction between the PEC cell 100 and the aqueous solution is required for allowing electrochemical reactions, leading to the water dissociation, to proceed. These reactions involve a two-electron reduction process for the H₂ generation and four-electron oxidizing process (four-hole absorption) for the generation of O₂. InₓGa₁₋ₓN semiconductors could be used to drive both reactions as long as the conduction and valence bands will span across the redox levels. As can be seen from FIG. 4, it is apparent that this band alignment can be normally realized only for InₓGa₁₋ₓN alloys with indium fraction x smaller than 15% (E_{g} 2.8 eV). Such alloys, unfortunately, would absorb light only above the blue domain of the visible spectra (469 nm) that carries around 3% of the energy in the terrestrial solar spectra.

In one or more embodiments of the present disclosure, a tandem nitride PEC cell 100 is provided that extends the operation of the electrochemical processes for Group III nitride alloys, such as InₓGa₁₋ₓN alloys, over the composition range from x=0 to x=43, and down to a band gap of 1.7 eV through particular band gap engineering using the addition of a silicon p/n junction in the PV cell 104, as explained herein. Similar to InGaN, for InₓAl₁₋ₓN or InₓAl_{y}Ga_{1-x-y}N alloys the addition of the silicon p/n junction in the PV cell 104 in the tandem configuration in the PEC cell 100 allows the extension of the spontaneous operation from x=0 down to x=71%, the latter concentration corresponding to a band gap of E_{g}=1.7 eV. Below the minimum level E_{g}(min) that can be occupied by the conduction band edge of InGaN, InAlN or InₓAl_{y}Ga_{1-x-y}N alloys, the photovoltage provided by the silicon PV cell 104 (−0.6V) does not provide sufficient energy lift for the electrons in the conduction band of the tandem to overcome the redox H⁺/H₂ potential.

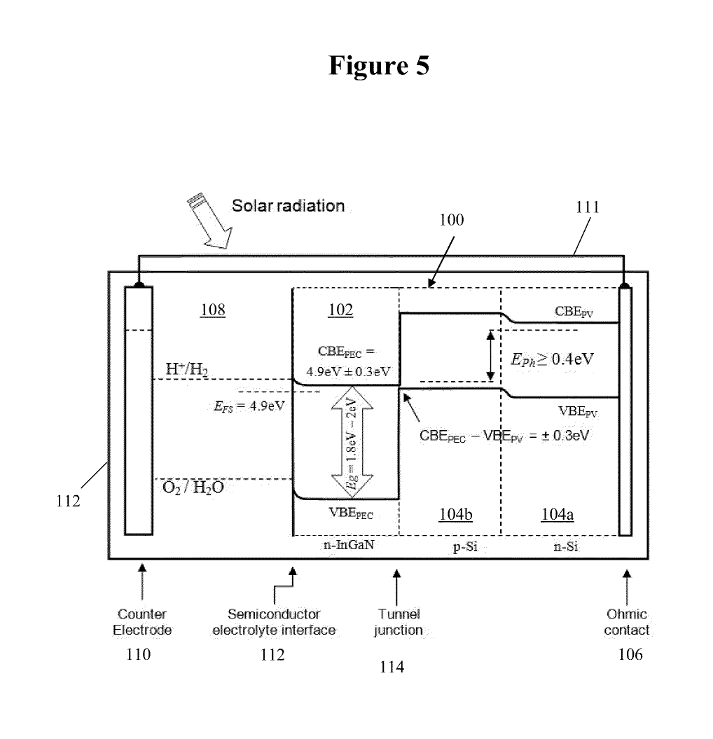

Referring now to FIG. 5, a schematic drawing of a single p-n junction tandem nitride photoelectrochemical (PEC) cell 100 is shown in accordance with one or more embodiments to be used in water or another aqueous solution 108 together with a counter electrode 110. The tandem nitride PEC cell 100 is immersed in water or an aqueous solution 108 held in a container 112 to allow for the generation of hydrogen and oxygen. The counter electrode 110 is electrically connected to the ohmic contact 106 through electrical connection 111, where counter electrode 110 and electrical connection 111 may be formed of any electrically conductive material that operates in accordance with the principles of operation of the various embodiments described herein.

In one or more embodiments, the materials forming the PEC semiconductor 102 and the PV cell 104 are selected and these elements are configured such that the conduction band of the PEC semiconductor 102 is aligned with the valence band of the PV cell 104, where the PEC semiconductor 102 is n-type, so as to form a low resistance tunnel junction 114 between the PEC semiconductor 102 and the PV cell 104. This low resistance tunnel junction 114 provides a perfect ohmic (no barrier) contact that facilitates the recombination of electrons and holes at the interface between the PEC semiconductor 102 and the PV cell 104. For example, the conduction band edge (CBE) of the PEC semiconductor 102 is aligned (e.g., within +/−0.3 eV) with the valence band edge (VBE) of the PV cell 104 in n-type PEC semiconductor 102 (as illustrated in FIG. 5). When the CBE of the PEC semiconductor 102 is described and/or claimed herein as being “substantially aligned” with the corresponding VBE of the PV cell 104, it is understood that the CBE and VBE are substantially aligned when within +/−0.3 eV of one another or are otherwise as closely aligned so as to allow the materials to form the low resistance tunnel junction 114 providing a perfect ohmic (no barrier) contact between the PEC semiconductor 102 and the PV cell 104.

In one or more embodiments, the materials forming the PEC semiconductor 102 and the PV cell 104 are further selected such that both the PEC semiconductor 102 and the PV cell 104 produce substantially the same number of electron-hole pairs upon exposure to solar radiation. This provides for the current matching conditions between the PEC semiconductor 102 and the PV cell 104 and the maximum performance of the tandem PEC cell 100. In this manner, the PV cell 104 not only provides an internal biasing voltage but also assures continuity of the current in the circuit between the PEC semiconductor 102 and the PV cell 104. In one or more embodiments, these conditions are satisfied by selecting the PEC semiconductor 102 to comprise In_{0.45}Ga_{0.55}N having a band gap of approximately 1.7-1.8 eV, while selecting the PV cell 104 to comprise Si having a band gap of approximately 1.1 eV. Some conventional materials used in tandem devices having too large of a band gap do not absorb enough photons to be an efficient PEC semiconductor 102 and also cannot be current matched to the large current generated by a Si PV cell 104. Still further, some of conventional materials used in tandem devices further possessed a very large misalignment between the conduction (valence) band of the first portion of the tandem device and the valence (conduction) band of the second portion of the tandem device, thereby making a good low resistance tunneling junction difficult to achieve between such conventional materials.

In one or more embodiments, a Si PV cell 104 is utilized that provides an open circuit of 0.5 to 0.6 V, which exceeds the 0.4 V required to lift the conduction band and Fermi energy level from E_{FS} (4.9 eV below the vacuum level) to above the hydrogen redox potential (4.5 eV below the vacuum level). By absorbing longer wavelength photons and separating the electron-hole pairs, the p-n junction in the Si PV cell 104 builds sufficient photo-potential, to position the Fermi energy level at the counter electrode 110 (through their interconnection through ohmic contact 106 and electrical connection 111) to a value over the hydrogen reduction energy level, needed to allow the free injection of electrons from the PEC semiconductor 102 into the water or aqueous solution 108.

The buildup of a potential of 0.5 V, for example, across the silicon p/n junction in PV cell 104, positions the conduction band and Fermi energy level of the counter electrode 110 and, in turn, tandem PEC cell 100 slightly over the reduction potential of hydrogen in the water splitting process, as can be seen from the band alignment of the InₓGa₁₋ₓN/Si tandem PEC cell 100 depicted at the right-side of FIG. 5. Therefore, the spontaneous development of redox reactions will be enabled for all InₓGa₁₋ₓN alloys. The extension of the band gap down to 1.7 eV, for example, provides the ability of the InₓGa₁₋ₓN semiconductor (PEC semiconductor 102) to absorb a significant portion of the energy in the light spectra, from UV down to a wavelength of 654 nm. Solar radiation absorbed in the silicon PV cell 104 generates carriers—electron-hole pairs—that are separated and swept across the low resistance tunnel junction 114, into the regions where they are majority carriers. The forward bias associated with the charge separation eventually elevates the conduction band level and the quasi Fermi energy into the n-Si of PV cell 104 and the counter electrode 110 to which is connected, above the hydrogen redox energy. The electrons are thus allowed to enter the aqueous solution 108 and induce the hydrogen reduction at the counter electrode 110 interface.

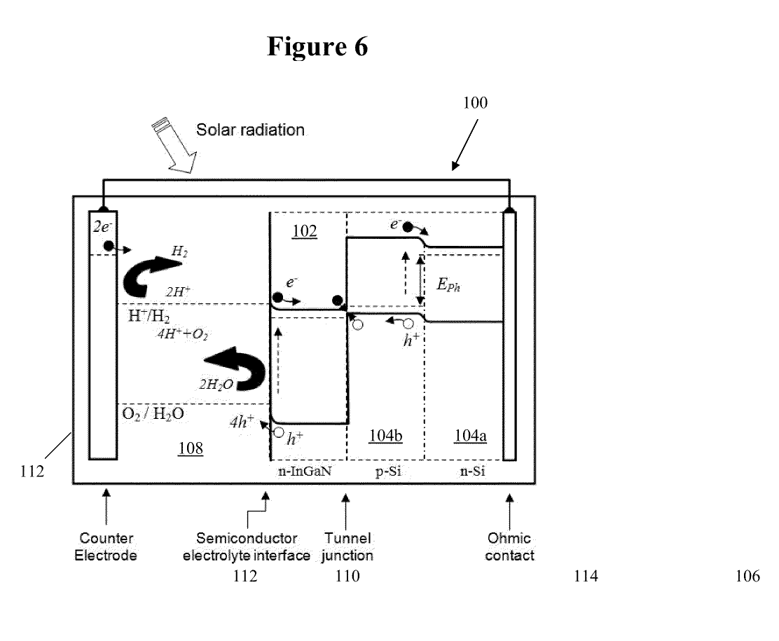

Absorption of solar radiation with higher energy takes place also in the InₓGa₁₋ₓN volume of PEC semiconductor 102 and electron-hole pairs are generated. The photogenerated electrons in the conduction band will ultimately reach the interface between PEC semiconductor 102 and PV cell 104 and tunnel to recombine with the photogenerated holes from the silicon side of PV cell 104. The holes left in the valence band of the InₓGa₁₋ₓN PEC semiconductor 102 will be swept over the PEC semiconductor/liquid interface 112 to oxygen redox potential enabling the oxygen generation. This behavior is possible because the two absorbing layers, silicon (PV cell 104) and the nitride semiconductor (PEC semiconductor 102) respectively, are connected in series through the tunnel junction 114, and their energy bands sum. The band alignment that corresponds to the operation under illumination of the silicon-nitride tandem PEC cell with one p/n junction is illustrated in FIG. 6.

Since the hydrogen (H₂) and oxygen (O₂) are generated at different interfaces that are physically removed from each other, namely at the counter electrode 110 interface and the PEC semiconductor/liquid interface 112, respectively, collection of the hydrogen and oxygen gases can be performed using separate gas collection equipment and storage reservoirs (not shown) as known to those skilled in the art.

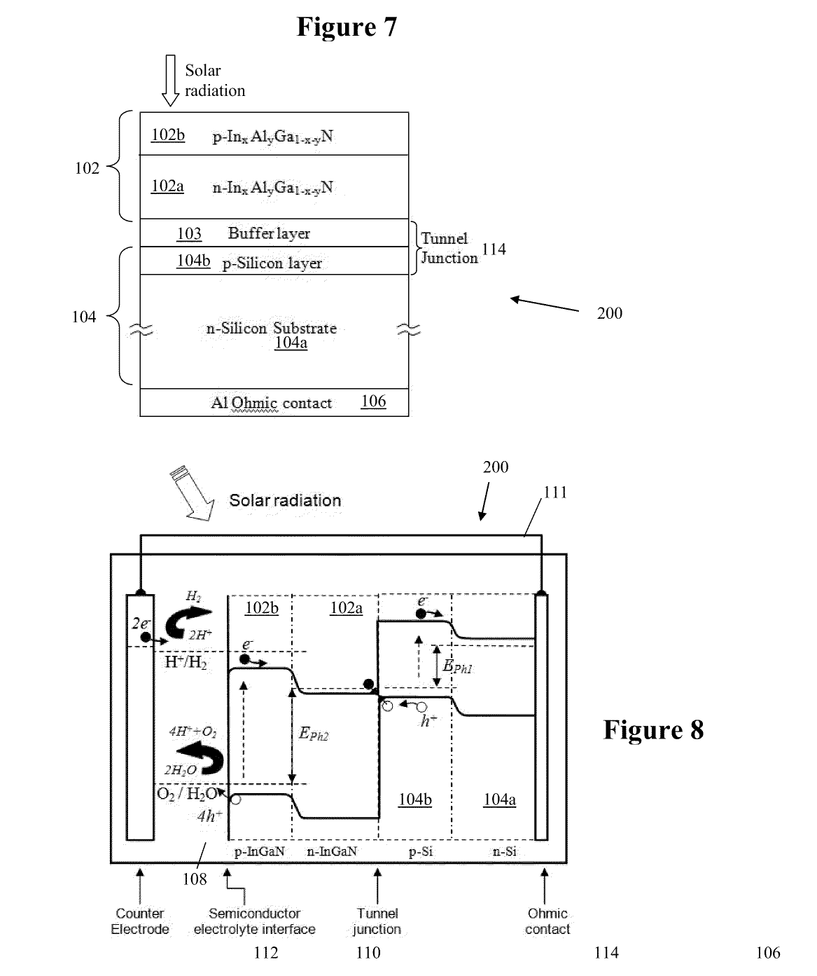

In one or more embodiments, a tandem PEC cell 200, similar to tandem PEC cell 100, may be formed in which an additional p-n junction is provided. A second p-n junction may be fabricated in the PEC semiconductor 102 that is deposited on top of the silicon PV cell 104 described previously that already has a first p-n junction. To form this second p-n junction, during the deposition process, the top layer of PEC semiconductor 102 material is p-doped with the appropriate specie of dopant, for example magnesium (Mg), to form p-type layer 102b in PEC semiconductor 102 at the outer surface of the otherwise n-type PEC semiconductor 102, thereby forming a p-type PEC semiconductor layer 102b over an n-type PEC semiconductor layer 102a, as illustrated by the tandem PEC cell 200 in FIG. 7. It is understood that PEC semiconductor may alternatively be p-type semiconductor materials which is in turn n-doped to form an n-type upper PEC semiconductor layer 102b over a p-type PEC semiconductor layer 102a.

In one or more embodiments, for the tandem PEC cell 200 having 2 p-n junctions with one p-n junction formed in the PEC semiconductor 102 and another p-n junction formed in the PV cell 104, a band alignment diagram that describes the operation under illumination is depicted in FIG. 8. Similar to the one junction structure, under illumination, the silicon p/n junction of the PV cell 104 is under forward bias and the quasi Fermi energy into the n-Si is elevated above the hydrogen redox energy. Therefore, at the counter electrode 110, electrons with energy above hydrogen redox energy level will enter the aqueous solution 108 and induce the hydrogen reduction reaction. The second p/n junction formed at the top of the InₓGa₁₋ₓN layer of the PEC semiconductor layer 102 will be also forward biased under illumination. This will cause the valence band of the p-InₓGa₁₋ₓN side of PEC semiconductor 102 to occupy an energy level bellow that of oxygen redox reaction. Provided the adequate acceptor density at the surface region of the p-InₓGa₁₋ₓN layer, the holes photo-generated will tunnel the narrow potential barrier and enter the aqueous solution 108 to promote the on-set of oxygen formation reaction. The advantage of having an additional p-n junction in the nitride layer of the PEC semiconductor 102 resides in the addition of photo-generated carriers contributing to the enhancement of the water splitting reaction rate and ultimately to the enhancement of the overall conversion efficiency.

For all compositions, the valence band of the PEC semiconductor 102 alloys will remain below the potential needed for driving the water oxidation, thus allowing holes to be transported from the PEC semiconductor 102 into the aqueous liquid 108 through interface 112 practically without any energetic barrier.

In one or more embodiments, the particular use of silicon p-n junction for PV cell 104 to support the deposition of a nitride semiconductor material for PEC semiconductor 102 provides the ability of obtaining a low resistance electric contact (tunnel junction 114) between the nitride layer (PEC semiconductor 102) and silicon (PV cell 104). Nitride semiconductor layers, such as InₓGa₁₋ₓN, are typically unintentionally n-doped due the presence of nitrogen vacancies in the material lattice. For an InₓGa₁₋ₓN band gap of 1.8 eV, the conduction band edge of the nitride semiconductor layer in PEC semiconductor 102 is aligned with the valence band edge of the p-type silicon layer in PV cell 104, constituting a tunnel junction that allows the carrier transport between the two materials with no energetic barrier for the electron-hole recombination.

Therefore, while the use of the InₓGa₁₋ₓN semiconductor alone for the PEC cells is limited at a minimum band gap of about 2.8 eV for band alignment considerations, the use of silicon as a deposition substrate and the formation of the silicon p/n junction, as described in this invention, allows photo-electro-chemical reactions to develop spontaneously, without the need for external biasing, for all InₓGa₁₋ₓN compositions down to the composition corresponding to 1.7 eV. Based on this range of InₓGa₁₋ₓN compositions, the invention also expands the spectra that can be absorbed for the purpose of carrier generation down to 1.7 eV and allows the formation of a very low series resistance between the silicon substrate of PV cell 104 and the nitride layer of PEC semiconductor 102.

While InₓGa₁₋ₓN compositions are described herein with respect to certain embodiments, it is understood that InₓAl₁₋ₓN, InₓAl_{y}Ga_{1-x-y}N or any other nitride semiconductor material could be utilized that perform similarly to the InₓGa₁₋ₓN compositions described herein and that satisfy the various conditions and features described herein of the tandem PV cell 100 or tandem PV cell 200.

Referring back to FIG. 6, when the tandem nitride PEC cell 100 is exposed to solar energy, energy transfers from photons in the solar energy to the tandem nitride PEC cell when the nitride semiconductor layer 102 and the silicon substrate 104 absorb lightwaves that contain at least the same amount of energy as their respective bandgap. A bandgap is the energy required to push an electron from a material's valence band to its conduction band. Based upon an experimental measurement of a 1.05±0.25 eV valence band offset between InN and GaN and the known electron affinity of GaN, InN is predicted to have an electron affinity of 5.8 eV, the largest of any known semiconductor. Forming the nitride semiconductor layer as an alloy of InGaN or InAIN allows a wide bandgap tuning range, 0.7 to 3.4 eV for InGaN and 0.7 to 6.0 eV for InAlN. In one or more embodiments, selecting a bandgap between about 1.7 eV to 1.9 eV, for example, further causes the generation of hydrogen gas and oxygen, simply by the application of solar radiation to the tandem nitride PEC cell 100, where hydrogen is generated without need for external power and also without petroleum products, such as natural gas.

In summary, in accordance with one or more embodiments, the tandem PEC cell 100 allows efficient, spontaneous dissociation of water into hydrogen and oxygen by satisfying some or all of the following conditions:
1. The PEC semiconductor 102 band gap is selected to be as small as possible (i.e., between 1.7 to 1.9 eV, preferably as close to 1.7 eV as possible) to maximize the absorbed solar energy.

2. In n-type PEC semiconductor 102, the valence band edge (VBE) has to be located below the oxygen redox potential whereas in the p-type PEC semiconductor 102, the conduction band edge (CBE) has to be above the hydrogen redox potential.

3. The biasing PV cell 104 has to provide at least 0.4 V for n-type PEC semiconductor 102 and at least 0.83 V for p-type PEC semiconductor 102.

4. The conduction band edge (CBE) for n-type PEC semiconductor 102 and the valence band edge (VBE) for p-type PEC semiconductor 102 has to be located in the vicinity of E_{FS} (within an approximate range E_{FS} +/−0.3 eV) to reduce the barriers for the charge transfer between the PEC semiconductor 102 and the aqueous solution 108.

5. To facilitate recombination of electrons and holes at the interface 114 between the PEC semiconductor 102 and PV cell 104, the CBE of the PEC semiconductor 102 has to be substantially aligned (within +/−0.3 eV) with the VBE of the PV cell 104, assuming that the PEC semiconductor 102 is n-type.

6. The materials in the tandem PEC cell 100 are preferably, although not required to be, resistant to corrosion from the aqueous solution 108. Since the tandem PEC cell 100 is immersed in the aqueous solution 108, it is preferably resistant to corrosion in order to improve the longevity of the effectiveness of the tandem PEC cell 100.

This process for generating hydrogen can be very useful in a number of applications, as hydrogen gas is a key fuel for next generation hydrogen fueled cars and also a key component in the renewable process of harvesting biofuels and biodiesel for replacement of oil based gasolines and jet fuels.

While the apparatus and method have been described in terms of what are presently considered to be the most practical and preferred embodiments, it is to be understood that the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

What is claimed is:

1. A photoelectrochemical (PEC) device for the generation of hydrogen and oxygen by dissociation of water upon exposure of the PEC device to light, comprising:
a tandem photoelectrochemical (PEC) cell, the tandem PEC cell including:
a photoelectrochemical (PEC) semiconductor including a photoactive material for absorbing a portion of the solar spectrum upon exposure to light to generate electron-hole pairs, wherein the PEC semiconductor includes a conduction band and a valence band having a band gap there between,
a photovoltaic (PV) cell connected in series with the PEC semiconductor, the PV cell configured to absorb a portion of the solar spectrum upon exposure to light to generate a biasing voltage for the tandem PEC cell, wherein the PV cell includes a conduction band and a valence band having a band gap there between; and
an ohmic contact connected to the PV cell;
wherein one of the conduction band and the valence band of the PEC semiconductor is aligned with a corresponding other of the valence band and the conduction band of the PV cell to form a low resistance tunnel junction between the PEC semiconductor and the PV cell;
a counter electrode connected to the ohmic contact;
wherein the tandem PEC cell functions as a work electrode and is placed together with the counter electrode in contact with an aqueous solution, such that, upon exposure to light, the PV cell generates an internal biasing voltage for the tandem PEC cell while the PEC semiconductor generates electron-hole pairs that interact with water present in the aqueous solution for causing dissociation of the water involving a reduction process to generate hydrogen and an oxidation process to generate oxygen.

2. The PEC device of claim 1, wherein the PEC semiconductor and PV cell are configured such that the biasing voltage generated by the PV cell causes hydrogen and oxygen redox potentials for water dissociation to be included within an energy span between the valence and conduction band edges of the PEC semiconductor.

3. The PEC device of claim 2, wherein the PV cell is configured to generate a biasing voltage of at least 0.4 V when the PEC semiconductor comprises an n-type semiconductor and a biasing voltage of at least 0.83 V when the PEC semiconductor comprises an p-type semiconductor.

4. The PEC device of claim 1, wherein the tandem PEC cell is configured such that the biasing voltage generated by the PV cell is selected to increase the Fermi energy level at the counter electrode so that there is substantially no energy barrier between the aqueous solution and the PEC semiconductor that would inhibit the flow of photogenerated electrons or holes.

5. The PEC device of claim 1, wherein the PEC semiconductor possesses a band gap between 1.7 eV to 1.9 eV while the PV cell possesses a band gap of approximately 1.1 eV.

6. The PEC device of claim 5, wherein the PEC semiconductor comprises a nitride semiconductor layer and the PV cell comprises a silicon substrate.

7. The PEC device of claim 6, wherein the nitride semiconductor layer comprises an alloy of InₓAl_{y} Ga_{1-x-y}N, where 0≦x, y≦1.

8. The PEC device of claim 1, wherein the PEC semiconductor and PV cell are configured such that a substantially equal number of electron-hole pairs are generated in both the PEC semiconductor and the PV cell upon exposure to light so that a current generated in both the PEC semiconductor and PV cell are substantially equal.

9. The PEC device of claim 1, wherein the PEC semiconductor is formed to include a first p-n semiconductor junction and the PV cell is configured to include a second p-n semiconductor junction.

10. The PEC device of claim 1, wherein the tandem PEC cell comprises a multi-layer, solid-state semiconductor structure in which certain layers of the multi-layer structure comprise the PEC semiconductor and certain other layers comprise the PV cell.

11. A tandem photoelectrochemical (PEC) cell for the spontaneous generation of hydrogen and oxygen from water, comprising:
a photoelectrochemical (PEC) semiconductor including a photoactive material for absorbing a portion of the solar spectrum upon exposure to light to generate electron-hole pairs, wherein the PEC semiconductor includes a conduction band and a valence band having a band gap there between, and
a photovoltaic (PV) cell connected in series with the PEC semiconductor, the PV cell configured to absorb a portion of the solar spectrum upon exposure to light to generate a biasing voltage for the tandem PEC cell, wherein the PV cell includes a conduction band and a valence band having a band gap there between;
wherein one of the conduction band and the valence band of the PEC semiconductor is aligned with a corresponding other of the valence band and the conduction band of the PV cell to form a low resistance tunnel junction between the PEC semiconductor and the PV cell;
an ohmic contact connected to the PV cell;
a counter electrode connected to the ohmic contact;
wherein the PEC semiconductor and PV cell are in contact with an aqueous solution, such that, upon exposure to light, the PV cell generates an internal biasing voltage for the tandem PEC cell while the PEC semiconductor generates electron-hole pairs that interact with water present in the aqueous solution for causing dissociation of the water involving a reduction process to generate hydrogen and an oxidation process to generate oxygen,
wherein the PEC semiconductor and PV cell are configured such that the biasing voltage generated by the PV cell is selected so that the Fermi energy level of the aqueous solution is either substantially aligned with the conduction band edge of the PEC semiconductor when the PEC semiconductor comprises an n-type semiconductor or substantially aligned with the valence band edge of the PEC semiconductor when the PEC semiconductor comprises a p-type semiconductor.

12. The tandem PEC cell of claim 11, wherein the PEC semiconductor and PV cell are configured such that the biasing voltage generated by the PV cell causes hydrogen and oxygen redox potentials for water dissociation to be included within an energy span between the valence and conduction band edges of the PEC semiconductor.

13. The tandem PEC cell of claim 12, wherein the PV cell is configured to generate a biasing voltage of at least 0.4 V when the PEC semiconductor comprises an n-type semiconductor and a biasing voltage of at least 0.83 V when the PEC semiconductor comprises an p-type semiconductor.

14. The tandem PEC cell of claim 11, wherein the PEC semiconductor possesses a band gap between 1.7 eV to 1.9 eV while the PV cell possesses a band gap of approximately 1.1 eV.

15. The tandem PEC cell of claim 14, wherein the PEC semiconductor comprises a nitride semiconductor layer and the PV cell comprises a silicon substrate.

16. The tandem PEC cell of claim 15, wherein the nitride semiconductor layer comprises an alloy of InₓAl_{y} Ga_{1-x-y}N, where 0≦x, y≦1.

17. The tandem PEC cell of claim 11, wherein the PEC semiconductor and PV cell are configured such that a substantially equal number of electron-hole pairs are generated in both the PEC semiconductor and the PV cell upon exposure to light so that a current generated in both the PEC semiconductor and PV cell are substantially equal.

18. The tandem PEC cell of claim 11, wherein the PEC semiconductor is formed to include a first p-n semiconductor junction and the PV cell is configured to include a second p-n semiconductor junction.

19. The tandem PEC cell of claim 11, wherein the tandem PEC cell comprises a multi-layer, solid-state semiconductor structure in which certain layers of the multi-layer structure comprise the PEC semiconductor and certain other layers comprise the PV cell.
